(19) United States
(12) Patent Application Publication
(10) Pub. No.: US 2015/0118411 A1
(43) Pub. Date: Apr. 30, 2015

(54) METHOD OF PRODUCING A GRAPHENE COATING ON A STAINLESS STEEL SURFACE

(71) Applicant: INSTITUT NATIONAL DE LA RECHERCHE SCIENTIFIQUE, QUEBEC (CA)

(72) Inventors: LUIS CARDENAS, VERDUN (CA); JENNIFER MACLEOD, BOUCHERVILLE (CA); JOSH LIPTON-DUFFIN, BOUCHERVILLE (CA); FEDERICO ROSEI, MONTREAL (CA)

(21) Appl. No.: 14/521,657

(22) Filed: Oct. 23, 2014

Related U.S. Application Data
(60) Provisional application No. 61/896,278, filed on Oct. 28, 2013.

(51) Int. Cl. C23C 16/26; C23C 16/02; C25F 3/24

(52) U.S. Cl. CPC C23C 16/26; C25F 3/24; C23C 16/0227
USPC 427/532

(57) ABSTRACT

A method of producing a graphene coating on a stainless steel surface, the method comprising the steps of electrochemically polishing of the stainless steel surface, and heating the polished stainless steel surface in contact with a carbon precursor.

### CROSS REFERENCE TO RELATED APPLICATIONS

This application claims benefit, under 35 U.S.C. §119(e), of U.S. provisional application Ser. No. 61/896,278, filed on Oct. 28, 2013. All documents above are incorporated herein in their entirety by reference.

### FIELD OF THE INVENTION

The present invention relates to method of producing a graphene coating on a stainless steel surface.

### BACKGROUND OF THE INVENTION

Stainless steel 316L (SS316L) is one of the most commonly used materials for the fabrication of implantable devices. SS316L is used extensively in coronary/cardiovascular stents, cranial fixation, orthopedic stents, dental implants and so on. However, it exhibits limited anticorrosive properties and mechanical resistance to friction, which can lead to degradation of the material and its subsequent release of metallic ions, including nickel ions in diverse oxidation states. Although SS316L contains molybdenum and a few passivating layers of different families of metal oxides, this protection is not sufficient to protect it against the localized forms of corrosion (pitting) associated with chloride ions in aqueous environments.

Graphene and related materials are known for their mechanical and anticorrosive properties. As one of the strongest materials, graphene possesses an ultrahigh Young's modulus of ˜1 TPa and an intrinsic fracture strength of ˜130 GPa. Extensive efforts have been devoted to the study of the anticorrosive properties of graphene, especially on copper and nickel surfaces. These studies have demonstrated that graphene growth by chemical vapor deposition on copper and nickel improves the anticorrosive properties of these metallic substrates. More recently, other studies suggested that graphene is an effective oxidation inhibitor on copper and silicon only over short time scales. Graphene membranes inhibit oxidation because they are impermeable to all standard gases, although the diffusion of O₂ and H₂O can occur at defects on the layer.

Graphene is also gathering interest in the biomedical field, where it is used as a new component for biosensors, tissue engineering, and drug delivery. Most biological tests, including biological response and safety tests, have been conducted on reduced graphene oxide (rGO) and graphene oxide (GO). This is because rGO and GO are more hydrophilic than pristine graphene. This hydrophilicity renders rGO and GO soluble in water and allows them to remain stably dispersed, thus facilitating biocompatibility testing. Existing evidence for the low toxicity and polar oxygen-hydrogen groups in rGO support the idea that this is a safe material and therefore suitable for biomedical applications.

Known methods of graphene synthesis include mechanical exfoliation of small-size graphene flakes, direct epitaxial growth of graphene from silicon carbide, and chemical vapor deposition (CVD). Both of these latter methods produce large and flat graphene flakes. Growing graphene coatings by CVD or other catalytic conversion method requires a catalytically active support, which enables the dissociation of carbon-containing precursor molecules and subsequent nucleation of graphene domains. Graphene synthesis has been carried out on SS304 using expensive evaporation methods, such as microwave plasma chemical vapor deposition (CVD) and the radio-frequency plasma enhanced CVD method.

### SUMMARY OF THE INVENTION

In accordance with the present invention, there is provided:
1. A method of producing a graphene coating on a stainless steel surface, the method comprising the steps of:
   electrochemically polishing of the stainless steel surface, and
   heating the polished stainless steel surface in contact with a carbon precursor,
   wherein said electrochemical polishing is carried out in an electrochemical cell comprising an electrolyte, a cathode, and the stainless steel surface as an anode, the cathode and the anode being submerged in the electrolyte.
2. The method of item 1, wherein the cathode is made of copper or stainless steel.
3. The method of item 1 or 2, wherein the electrolyte is a mixture of a phosphoric acid and sulfuric acid.
4. The method of any one of items 1 to 3, further comprising cleaning the stainless steel surface prior to electrochemical polishing.
5. The method of any one of items 1 to 4, further comprising cleaning the stainless steel surface after electrochemical polishing.
6. The method of any one of items 1 to 5, further comprising keeping the polished stainless steel surface in the electrolyte up until the heating in contact with the carbon precursor is carried out.
7. The method of any one of items 1 to 6, wherein a solution of the carbon precursor has been cast on the stainless steel surface and allowed to dry before heating.
8. The method of item 7, wherein the solution is drop cast on the stainless steel surface.
9. The method of item 7, wherein the solution is spin-coated on the stainless steel surface.
10. The method of any one of items 1 to 6, wherein, during heating, the carbon precursor is gasified and allowed to reach the stainless steel surface.
11. The method of any one of items 1 to 10, wherein the carbon precursor is an organic compound comprising carbon and hydrogen atoms, optionally oxygen and/or nitrogen atoms and/or halogen atoms, but free of metallic atoms.
12. The method of item 11, wherein the carbon precursor is an alkane, an alcohol or an acid.
13. The method of item 11, wherein the carbon precursor comprises one or more fused aromatic rings.
14. The method of item 13, wherein the carbon precursor is pentacene, anthracene, tetracene, naphthalene, and coronene.
15. The method of item 14, wherein the carbon precursor is coronene.
16. The method of any one of items 1 to 15, wherein the stainless steel surface is heated at temperature of about 600° C. or more.
17. The method of item 16, wherein the stainless steel surface is heated at temperature of about 800° C.
18. The method of any one of items 1 to 17, wherein the stainless steel surface is heated for about 30 minutes.
19. The method of any one of items 1 to 18, wherein the stainless steel surface is heated in a vacuum.
20. The method of any one of items 1 to 18, wherein the stainless steel surface is heated in a reducing atmosphere.
21. The method of any one of items 1 to 18, wherein the stainless steel surface is heated in an atmosphere of the carbon precursor.
22. The method of any one of items 1 to 21, further comprising quickly cooling the stainless steel surface.
23. The method of any one of items 1 to 22, wherein the stainless steel is a nickel-containing stainless steel.
24. The method of claim 23, wherein the stainless steel is an austenitic stainless steel.
25. The method of claim 23 or 24, wherein the stainless steel is an AISI grade 304, 316, or 316L stainless steel.
26. The method of claim 25, wherein the stainless steel is an AISI grade 316L stainless steel.
27. The method of any one of claims 1 to 26, wherein the graphene coating comprises pristine graphene.
28. The method of any one of claims 1 to 26, wherein the graphene coating comprises graphene oxide.
29. The method of any one of claims 1 to 26, wherein the graphene coating comprises reduced graphene oxide.

### BRIEF DESCRIPTION OF THE DRAWINGS

In the appended drawings:

FIG. 1 shows XPS spectra of Ni2p_{3/2} for untreated SS 316L (bottom) and treated SS 316L (top);

FIG. 2 shows the XPS spectra of Cr 2p_{3/2} core level for untreated SS 316L (bottom) and treated SS 316L (top);

FIG. 3 shows the XPS spectra of Fe 2p_{3/2} core level for untreated SS 316L (bottom) and treated SS 316L (top);

FIG. 4 shows (a) Raman spectra corresponding to rGO (top curve) and coronene (bottom curve) on the same area where optical images were taken for: (b) rGO/SS 316L and (c) coronene/SS316L;

FIG. 5 shows DFT optimized structures for (a) single-coronene, (b) trimer-coronene and (c) tetramer-coronene, with (d) the calculated Raman spectra for each configuration (from top to bottom: tetramer, trimer, and monomer), and inset: C/H vs I_{D}/I_{G} ratios (from left to right: monomer, trimer, tetramer);

FIG. 6 shows XPS spectra of (a) C₁ₛ, and (b) O₁ₛ on rGO/SS;

FIG. 7 shows XPS spectra of Ni2p_{3/2} for untreated SS 316L (bottom), treated SS 316L (middle) and SS 316L treated for 4 days (top); and

FIG. 8 shows XPS spectra of Cr 2p_{3/2} for untreated SS 316L (bottom), treated SS 316L (middle) and SS 316L treated for 4 days (top); and

FIG. 9 shows XPS spectra of Fe 2p_{3/2} for untreated SS 316L (bottom), treated SS 316L (middle) and SS 316L treated for 4 days (top); and

FIG. 10 shows (a) Raman spectra corresponding to rGO (top curve) and amorphous carbon (bottom curve) on the same area where optical images were taken for (b) rGO/SS 316L and (c) amorphous carbon/untreated SS316L.

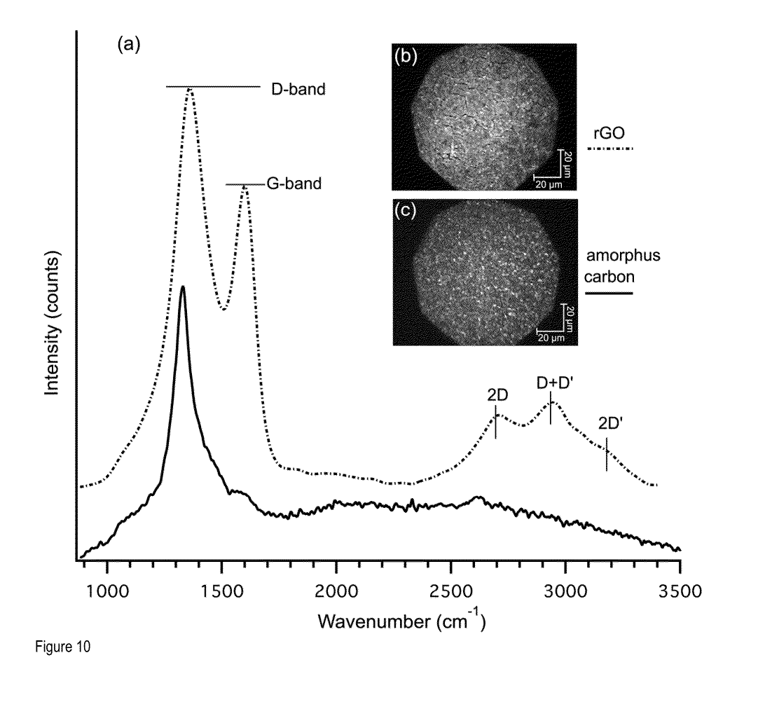

### DETAILED DESCRIPTION OF THE INVENTION

Turning now to the invention in more details, there is provided a method of producing a graphene coating on a stainless steel surface.

As described below, depending on the exact conditions used in the present method, the graphene coating produced can be comprised of pristine graphene, graphene oxide (graphene that is oxidized), or reduced graphene oxide as shown below.

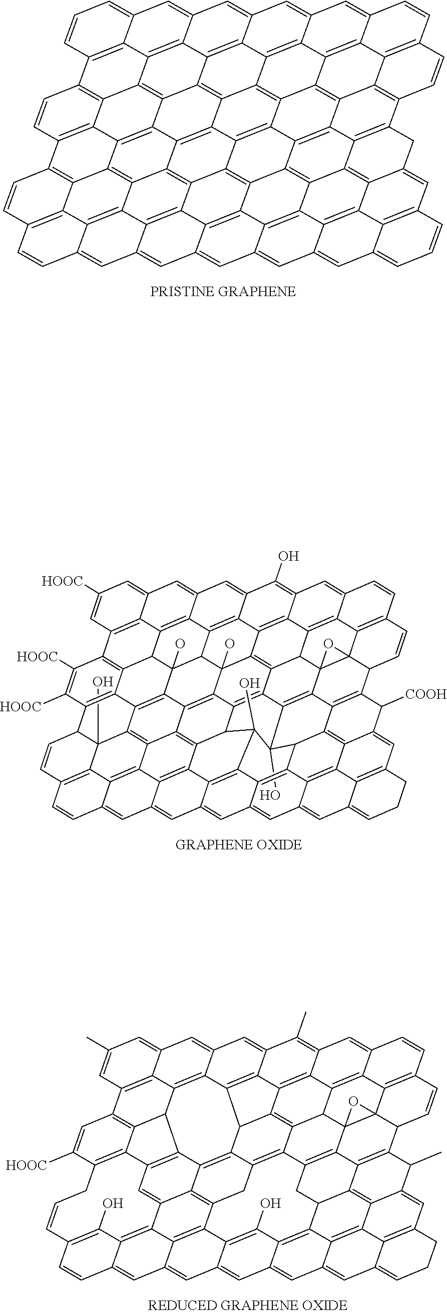

Reduced graphene oxide is graphene oxide that is more or less reduced. It is generally considered that a Raman spectrum in which the G band (around 1595 cm⁻¹) and the D band (around 1350 cm⁻¹) have the same height is indicative of graphene oxide, while a D band higher than the G band is indicative of reduced graphene oxide.

The stainless steel (SS) can be any stainless steel alloy, including austenitic, ferritic, and martensitic stainless steels, preferably austenitic stainless steel. Preferred stainless steels are those that comprise nickel, particularly those with higher nickel concentrations. Exemplary stainless steels include austenitic stainless steels, for example those of AISI grades 304, 316, and 316L. Stainless steels 316 and 316L are suitable for use in a broad range of biological applications, including implantable devices. Stainless steel 304 would be more desirable for electrical applications, for example use in lithium-ion batteries as current collector.

The method of the invention comprises the step of electrochemical polishing of the stainless steel surface. Indeed, as shown the comparative example below, no graphene formed on stainless steel that was not previously electrochemically polished.

This polishing removes the layers of metal oxides naturally present at the surface of the stainless steel. It was also observed that this polishing increases the concentration of various metals, including nickel, iron(0) and chromium(0) at the surface of the stainless steel. Without being bound by theory, it is believed that one or more of these surface atoms are catalytically active and allow for the formation of the necessary sp2 bonds during graphene formation. In particular, it is proposed that the nickel atoms could be involved in this process, since in its pure state nickel is already a known catalyst for graphene growth.

The electrochemical polishing is carried out as known in the art, for example, to reduce roughness, clean stainless steel, etc. See Electropolishing Stainless Steel, in Materials and Application Series, Volume 11, by Euro Inox (European Stainless Steel Development Association), incorporated herein by reference, for details. The electrochemical polishing can be carried out in an electrochemical cell comprising an electrolyte as well as the stainless steel surface (as the anode) and a cathode, both submerged in the electrolyte. The cathode may be made of any suitable metal known in the art, for example stainless steel, copper, lead. In embodiments, the cathode is made of copper. The electrolyte may be any suitable electrolyte known in the art. Common electrolytes include mixtures of phosphoric acid (e.g. orthophosphoric acid) and sulfuric acid. Other acids may also be used. In embodiments, the electrolyte comprises 40 parts phosphoric acid (85%), 10 parts of distilled deionized water, and 5 parts sulphuric acid (98%). The operating condition can generally be as follows:
Current density: 5-75 A/dm², preferably 50 A/dm²,
Temperature: room temperature to 75° C., preferably room temperature, and
Exposure time: 2-20 minutes, preferably 5 minutes.

The efficacy of the electrochemical polishing will be proportional by the current applied, the efficiency of the electrolyte, and the exposure time.

As needed and as known in the art, the stainless steel surface may be cleaned prior to electrochemical polishing to remove surface oils, greases, and other contaminants.

After electrochemical polishing, the stainless steel surface can be kept in the electrolyte until use. It was observed by the present inventors that surface metal enrichment slowly continued in such conditions.

Once the surface is taken out of the acid, it should be cleaned, for example by sonication in ethanol, to remove residual electrolyte and any by-products of the polishing reaction. It should be noted however that the polished stainless steel surface should not be left out of the acid for long periods of time before further use. This is because an undesirable layer of oxide will form on the surface. The present inventors observed that polished stainless steel surface can be left out of acid for up to about 24 h without significant deleterious effect.

Then, the polished stainless steel surface is heated while being in contact with a carbon precursor.

Contact between the polished stainless steel surface and the carbon precursor can be achieved by two main ways: (A) before heating a solution of the carbon precursor can be cast on the surface or (B) during heating the carbon precursor can be gasified and allowed to reach the surface (chemical vapor deposition). In both cases, the extent and thickness of the graphene coating produced will depend on the concentration of the carbon precursor on the surface.

The method for casting the solution of the carbon precursor onto the polished stainless steel surface is not crucial to the invention. In embodiments, the solution is deposited on the surface by drop casting, spin coating, etc. The solution should then be allowed to dry as needed before heating.

Chemical vapor deposition of the carbon precursor is suitable for volatile carbon precursors only. When using chemical vapor deposition, the carbon precursor (in gaseous state) will typically be the only gas present during heating of the polished stainless steel surface.

The carbon precursor can be any such precursor known in the art. These are generally organic compounds comprising carbon and hydrogen atoms, optionally oxygen and/or nitrogen atoms and/or halogen atoms, but generally free of metallic atoms. Exemplary carbon precursors include lower alkanes (such as methane), lower alcohols (such as methanol, ethanol, and propanol), and acids (such as trimesic acid). Preferred carbon precursors include one or more fused aromatic rings. Non-limiting examples of such carbon precursors include pentacene, anthracene, tetracene, naphthalene, and coronene:

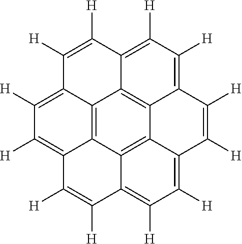 [SMILES: c1cc2ccc3ccc4ccc5ccc6ccc1c1c2c3c4c5c61]

The heating allows for catalytic growth of graphene on the surface through reaction with the carbon precursor. Thus, the surface must be heated to a temperature high enough to allow for this reaction to happen. For example, suitable temperature can range from about 600° C. up to about 1500° C., typically around about 1000° C. It was observed during the experiments described below, that a temperature around 800° C. allowed the formation of a uniform graphene layer with reduced grain boundaries. These temperatures are surprisingly lower than would be expected for this type of reaction without the presence of a catalyst (around 2000° C.). This advantageous reduction in required temperatures is believed to be attributable to the presence of catalytically active nickel (or other metal) atoms on the surface.

The time spent at the required temperature will depend on several factors including the temperature itself and the nature of the carbon precursor. For each system, a minimal reaction time can easily be ascertained through analysis of the formed graphene coating. During the experiments described below, the same good results were observed for heating times of 30, 60, and 90 minutes.

The exact nature of the graphene coating produced will depend on the atmosphere in which the heating takes place and on the nature of the carbon precursor. Generally, the more oxygen atoms (provided by the precursor or the atmosphere) are present in the system, the more the graphene will be oxidized. However, heating in a reducing atmosphere will tend to reduce the graphene oxide. Such reducing atmosphere can be any of those known in the art. In embodiments, the reducing atmosphere is composed of 98% nitrogen (or another inert gas) and 2% hydrogen. Heating in vacuum in the presence of a carbon precursor that does not comprise oxygen atoms will tend to produce more pristine graphene.

As a last step, the coated stainless steel surface can quickly cooled under the same atmosphere as that used for heating. This should reduce the incidence of side reactions during cooling. Herein, “quickly cooled” does not mean quenching of the surface. Quickly cooling rather refers to cooling rates such as those obtained by turning off the heat source and continuing circulating said atmosphere.

The method of the invention makes stainless steel suitable for graphene growth. This method increases the surface concentration of various low-oxidation state metals (Ni, Cr, Fe) through electrochemical polishing. The application of a direct current to an anode sample immersed in an electrolyte causes dissolution of the surface oxide and removes these passivating layers until these metals are exposed. These increases in metal concentration render the surface catalytically active and suitable for graphene growth. It is believed that the metal-rich surface reduces the energy barrier for the conversion of carbon precursor into graphene. Graphene can therefore be prepared at relatively low pressures and temperatures, reducing the required input energy and therefore overall expense. This method is also scalable.

It has been observed that the produced graphene coatings have good cell viability and stability. Such materials are expected to be useful in a broad range of biological applications, especially when considering the ability to controlling its properties such as available reactive oxygen species (through controlling oxygen input in the system and using a more or less reducing atmosphere) and effective graphene surface area (through controlling the concentration of the carbon precursor) and considering its low cytotoxicity and increased corrosion resistance. Still with regards to biological applications, it should be noted that carbon-metal bonds were not detected in the C₁ₛ and O₁ₛ states and that no traces of Fe₂ₚ and Ni₂ₚ were observed by XPS, indicating that the graphene coating is not chemically bonded to the substrate. Thus, the produced reduced graphene oxide coatings are expected to improve the mechanical and biological properties rendering steel suitable for biomedical and biotechnological applications.

### DEFINITIONS

The use of the terms “a” and “an” and “the” and similar referents in the context of describing the invention (especially in the context of the following claims) are to be construed to cover both the singular and the plural, unless otherwise indicated herein or clearly contradicted by context.

The terms “comprising”, “having”, “including”, and “containing” are to be construed as open-ended terms (i.e., meaning “including, but not limited to”) unless otherwise noted.

Recitation of ranges of values herein are merely intended to serve as a shorthand method of referring individually to each separate value falling within the range, unless otherwise indicated herein, and each separate value is incorporated into the specification as if it were individually recited herein. All subsets of values within the ranges are also incorporated into the specification as if they were individually recited herein.

All methods described herein can be performed in any suitable order unless otherwise indicated herein or otherwise clearly contradicted by context.

The use of any and all examples, or exemplary language (e.g., “such as”) provided herein, is intended merely to better illuminate the invention and does not pose a limitation on the scope of the invention unless otherwise claimed.

No language in the specification should be construed as indicating any non-claimed element as essential to the practice of the invention.

Herein, the term “about” has its ordinary meaning. In embodiments, it may mean plus or minus 10% or plus or minus 5% of the numerical value qualified.

Unless otherwise defined, all technical and scientific terms used herein have the same meaning as commonly understood by one of ordinary skill in the art to which this invention belongs.

Other objects, advantages and features of the present invention will become more apparent upon reading of the following non-restrictive description of specific embodiments thereof, given by way of example only with reference to the accompanying drawings.

### DESCRIPTION OF ILLUSTRATIVE EMBODIMENT

The present invention is illustrated in further details by the following non-limiting examples.

### Example 1

### Reduced Graphene Oxide Growth on 316L Stainless Steel

Below, we report a new method for the growth of reduced graphene oxide (rGO) on stainless steel (SS) 316L foils. Using Raman spectroscopy, X-ray photoelectron spectroscopy (XPS) and density functional theory (DFT) calculations, we demonstrate that increasing nickel, chromium and iron surface concentrations by electrochemical etching enables the growth of rGO. More specifically, Raman spectroscopy shows the G and D bands for oxidative species of graphene at 1595 cm⁻¹ and 1350 cm⁻¹, respectively, and gives a I_{D}/I_{G} ratio of 1.2, indicating a moderate degree of oxidation. XPS shows —OH and —COOH groups in the rGO stoichiometry, and demonstrates the influence of metallic species present in stainless steel on the rGO.

Electropolishing of SS 316L.

In an electrochemical cell, a 0.9 mm thick SS316L (60 mm²) foil mirror polished on one side was used as the anode, while a Cu plate was used as the cathode. The electrolyte solution was made of 40 ml phosphoric acid (85%, supplier), 10 ml distilled deionized water, and 5 ml sulphuric acid (98%, supplier). The voltage was kept constant at 3.8 V, while the current was 0.3 A (current density=50 A/dm²). The cell was operated for 5 min.

Cleaning.

Following electropolishing, the SS316L foil was cleaned by sonication in ethanol.

Preparation of rGO Coating.

Coronene (97%, Sigma Aldrich) was dissolved in trichlorobenzene (TCB, purity, supplier) at a concentration between 10⁻⁴ and 10⁻⁵ M. The coronene solution was drop cast onto the electropolished SS316L. Samples were annealed to between 600-800° C. for 30 minutes under a flowing atmosphere of 98% nitrogen and 2% hydrogen in a quartz tube. After annealing, the furnace was cooled quickly, while the N₂/H₂ environment was maintained.

Characterization.

Raman spectra were recorded in the 800-3500 cm⁻¹ region of using an inVia Raman microscope—Renishaw with a laser wavelength of 514 nm. Scanning with this instrument was used to evaluate the presence and uniformity of rGO on the SS316L. X-ray photoelectron spectroscopy was performed using a polychromatic Mg Kα source, and revealed well-resolved peaks corresponding to C₁ₛ, O₁ₛ, Ni₂ₚ, Cr₂ₚ, Fe₂ₚ. Each spectrum was decomposed in a single Voigt function with an overall FWHM of approximately 1.4 eV.

Ab-Initio Calculations.

DFT calculations were carried out in order to identify the vibrational frequencies and Raman intensities for the coronene monomer, dimer and trimer configurations. Calculations were performed using Gaussian 09 (see Gaussian 09, Revision A.1, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zhen, and D. J. F. Gaussian 09.) by function theory (DFT) at the B3LYP level (see Becke, A. D. J. Chem. Phys. 1993, 98, 5648.) using the 6-31G basis set.

Results.

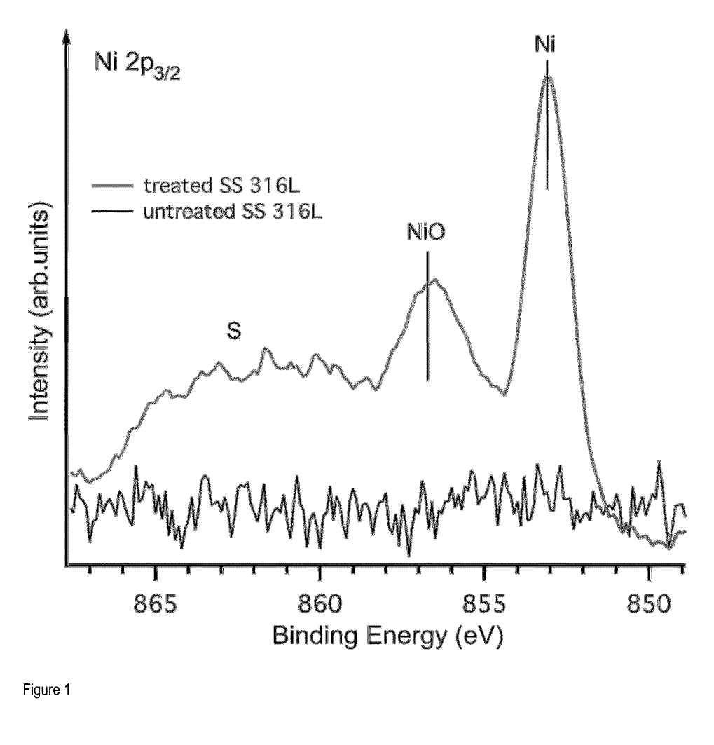

FIG. 1 shows the XPS spectra of Ni 2p_{3/2} core level for untreated SS 316L (bottom) and treated SS 316L (top). This figure reveals that electrochemical polishing of bare SS316L produces a nickel-rich surface. The Ni 2p_{3/2} spectrum for untreated SS316L indeed indicates an absence of nickel on the surface. On the other hand, the Ni 2p_{3/2} spectrum for treated SS316L reveals a nickel-rich surface with two main contributions: metallic nickel (Ni) at ca. 853.2 eV, and nickel (II) oxide (NiO) at ca. 856.6 eV, and a shoulder (S), which can be attributed to related satellite peaks.

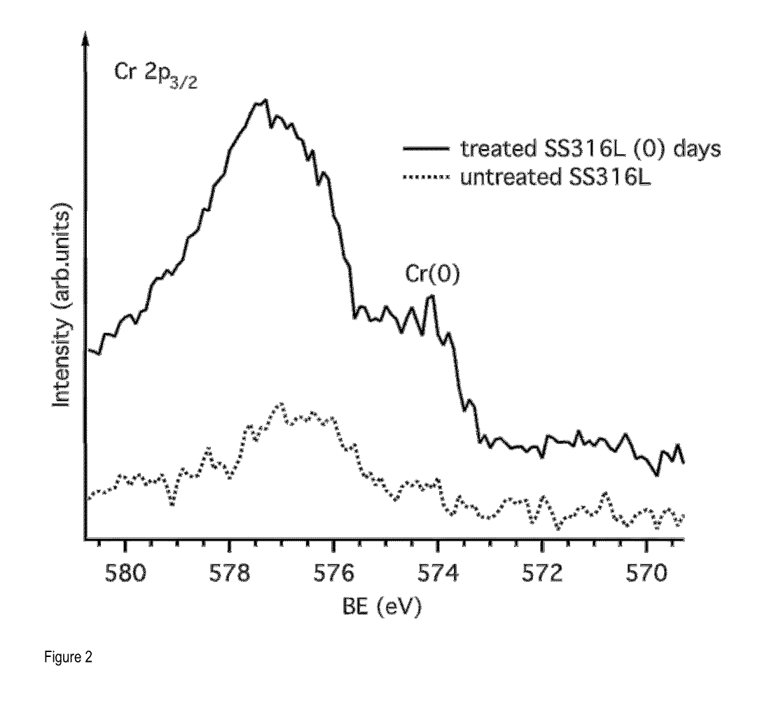

FIG. 2 shows the XPS spectra of Cr 2p_{3/2} core level for untreated SS 316L (bottom) and treated SS 316L (top). This figure reveals that electrochemical polishing of bare SS316L produces a chromium-rich surface.

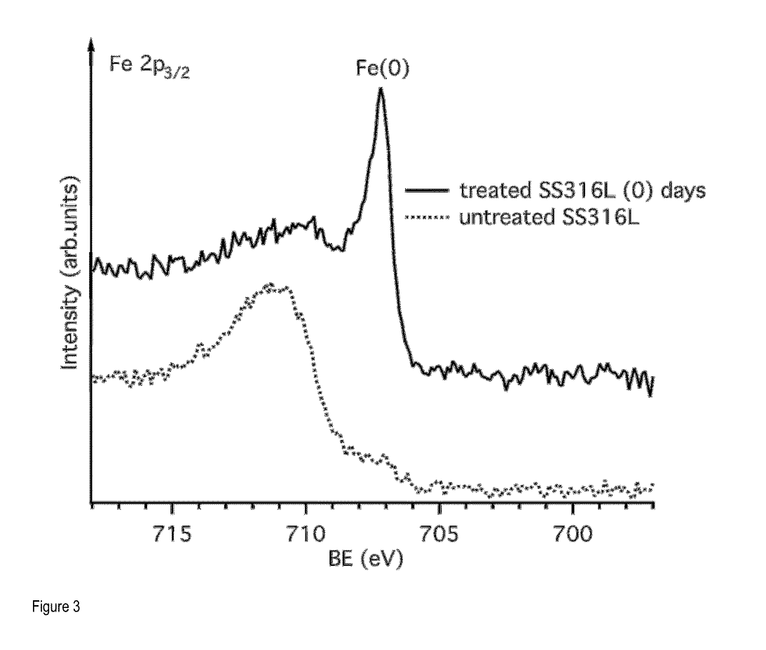

FIG. 3 shows the XPS spectra of Fe 2p_{3/2} core level for untreated SS 316L (bottom) and treated SS 316L (top). This figure reveals that electrochemical polishing of bare SS316L produces an iron-rich surface.

Coronene was applied dropwise from solution on the electropolished surface. This surface was subsequently annealed at 800° C. for 30 minutes (see experimental methods). Coronene was used because of its relatively high thermo-resistivity: dimerisation happens in powder samples between 550° C. and 600° C.

From a structural point of view, coronene is essentially a small flake of graphene, comprising sp2 carbon formed by six cyclobenzene rings. The scheme below shows (a) the chemical structure of coronene and (b) part of the chemical structure of the product obtained through polymerization of coronene by the dehydrogenation process at play in the present method.

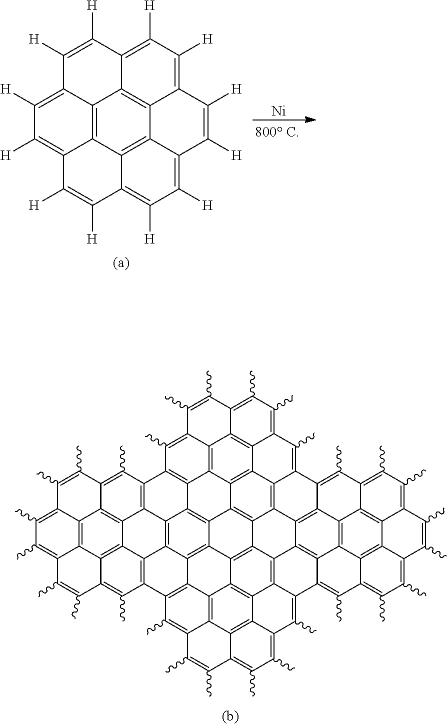

Raman spectroscopy has been widely used on carbonaceous systems such as carbon nanotubes, fullerenes, and graphene. This powerful technique allows observing spectroscopic signatures of hybridized carbon sp2 bonds present in honeycomb networks. Raman spectra exhibit some typical bands for carbonaceous materials; among them are the G band at ca. 1595 cm⁻¹ and the D band around 1350 cm⁻¹ for oxidative species of graphene. The G band has been ascribed to a stretching mode attributable to sp2-hybridized carbon atoms in honeycomb network. The D band originates from disordered and amorphous carbon bonds, and originates from the breathing mode of k-point phonons of A₁ symmetry. At high wavenumbers, a series of overtones of both D and G are visible between ca. 2700 and 3300 cm⁻¹.

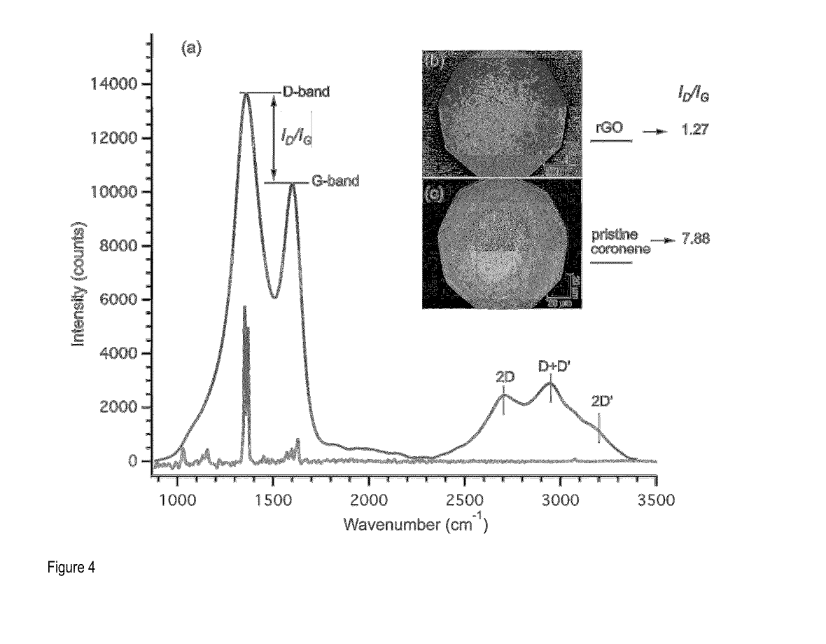

The Raman spectrum of pristine coronene (FIG. 4a, bottom curve) shows a strong and sharp D band at 1359 cm⁻¹, with a small G line at ca. 1600 cm⁻¹ The intensity amplitude ratio I_{D}/I_{G} is 7.88, consistent with the relatively small spatial extent of the sp2 network in coronene.

The Raman spectrum for the annealed coronene film on treated SS316L (FIG. 4a, top curve) has broader and more intense peaks. The G band is broadened and shifted to 1597 cm⁻¹, whereas the D band appears at 1359 cm⁻¹, in accord with earlier reports of rGO. It is known that the average size of sp2-bonded graphitic domains is inversely proportional to the I_{D}/I_{G} ratio. The ratio I_{D}/I_{G} observed herein is about 1.2, which is consistent with that reported for other rGO related materials, and indicates that the sp2 network extends much further than it does in the coronene molecule. This is a clear hallmark of polymerization and expansion of the graphene lattice. These results unequivocally support the formation of rGO on the SS316L surface.

FIGS. 4b and 4c are optical microscopy images of rGO and the pristine coronene in the region where the Raman spectra were acquired. Two important features are discernible in the image of the treated sample (FIG. 4b):

i) a color variation due to the intrinsic reflectance of graphene oxide; and

ii) graphene grain boundaries visible in the optical image, consistent with previous observations.

Neither of these features is present in the image of the coronene-covered sample (FIG. 4c).

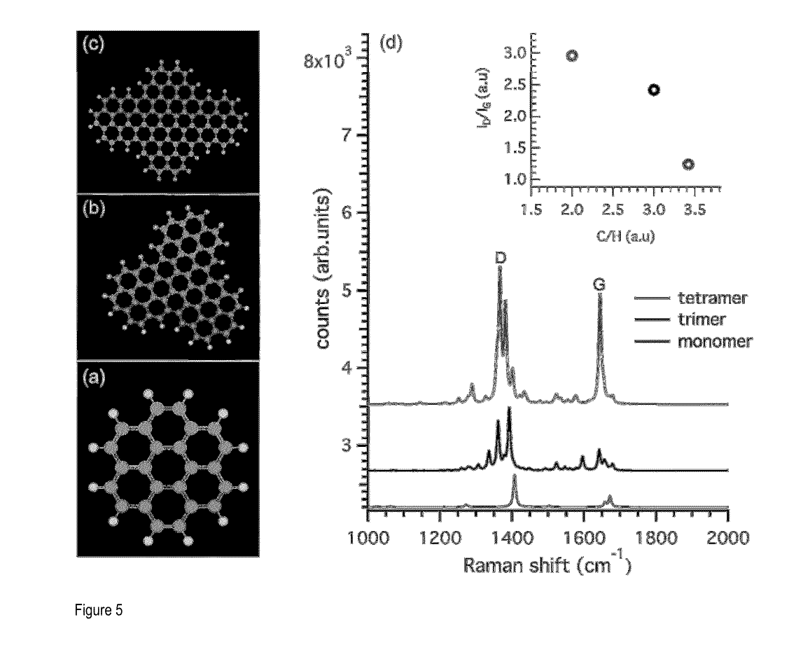

Density functional theory (DFT) at the B3LYP level has been used to study the geometries and Raman spectra of coronene in monomer (FIG. 5a), trimer (b), and tetramer (c) configurations. A calculated Raman spectrum (FIG. 5d) for a coronene monomer has D and G bands at ca. 1407 cm⁻¹ and ca. 1656 cm⁻¹ respectively along with an I_{D}/I_{G} ratio of ˜3. The inset of FIG. 5 shows the evolution of the I_{D}/I_{G} ratio for monomer, trimer, and tetramer of coronene. This ratio decreases with the size of the coronene oligomer, which is consistent with the spatial expansion of the sp₂-graphitic bonds network.

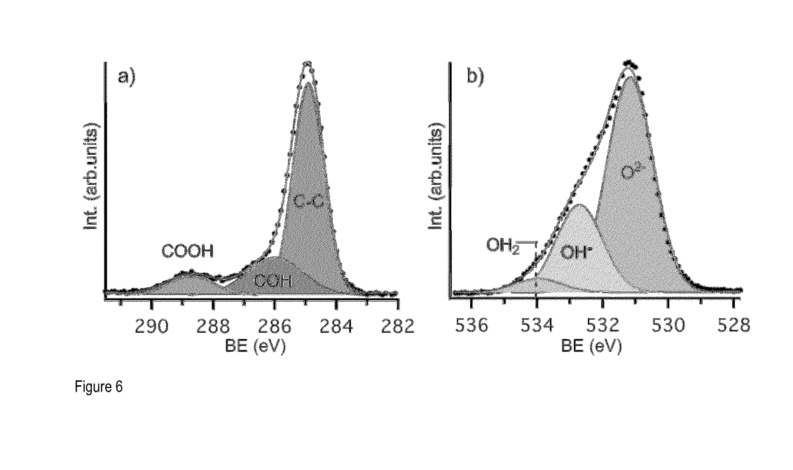

FIG. 6 shows XPS spectra of the C₁ₛ (a), and O₁ₛ (b) core levels obtained from the rGO/SS316L sample. The C₁ₛ peak in FIG. 6a is broad, with a shoulder at high binding energy. The contribution located at ≈284.9 eV is attributable to C—C bonds. The shoulder can be fitted with by two contributions, one corresponding to COH groups (286.3 eV), and the other to —COOH groups (288.6 eV). FIG. 6b shows core level spectrum of O₁ₛ, which can be fitted by three peaks attributable to O²⁻, hydroxyl groups OH— and hydrate or water OH₂.

Both the C₁ₛ and O₁ₛ spectra contain hydroxyl contributions, unequivocally confirming their presence. These XPS data are consistent with the Lerf and Klinowski model for GO, in which carboxylic acid groups are primarily located on the periphery of the basal plane of platelets of GO, whereas hydroxyl groups incorporated in the graphene structure. A XPS analysis to determine elemental composition showed that the aforementioned functional groups (—OH— or —COOH) cover about 9% of the surface, which is very close to the 10% coverage expected for rGO.

Carbon-metal bonds were not detected in the Cis state. Furthermore, no traces of Fe₂ₚ and Ni₂ₚ were observed by XPS. This indicates that the rGO is not chemically bonded to the substrate.

Metallic Cr₂ₚ was observed on the bare treated SS316L sample. It has recently been reported that the presence of chromium on the surface may be detrimental to graphene growth under certain conditions. However, no traces of metallic Cr(0) were observed by XPS on the rGO/SS316L surface.

Conclusions.

An rGO coating was synthesized from coronene by solution deposition on electrochemically polished stainless steel and subsequent annealing. Although SS316L is not a known platform for catalytic growth, we have demonstrated that electrochemical etching allows rGO growth.

### Example 2

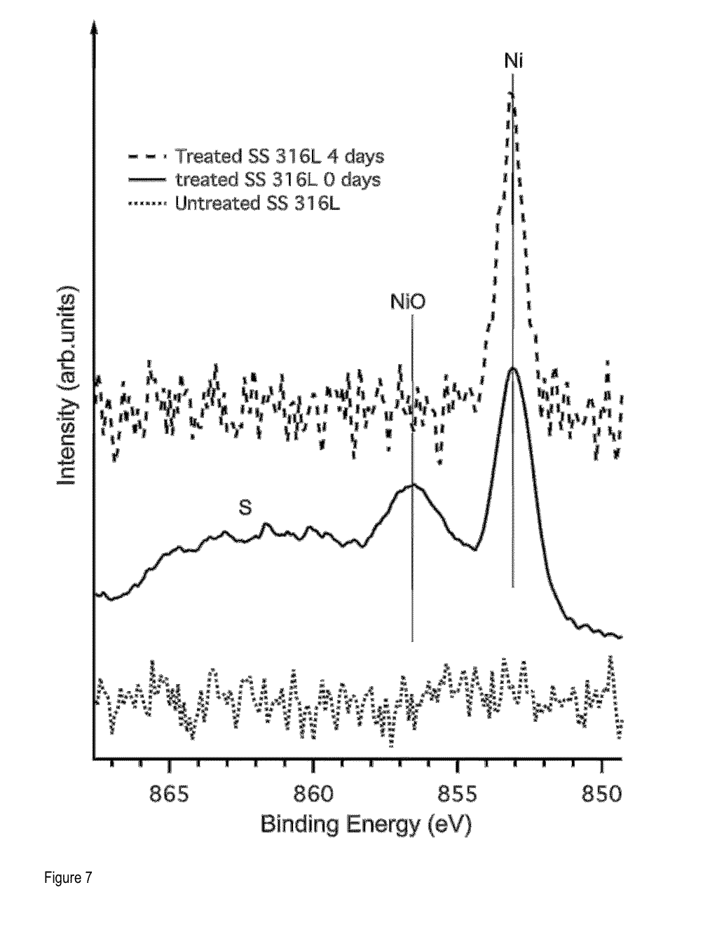

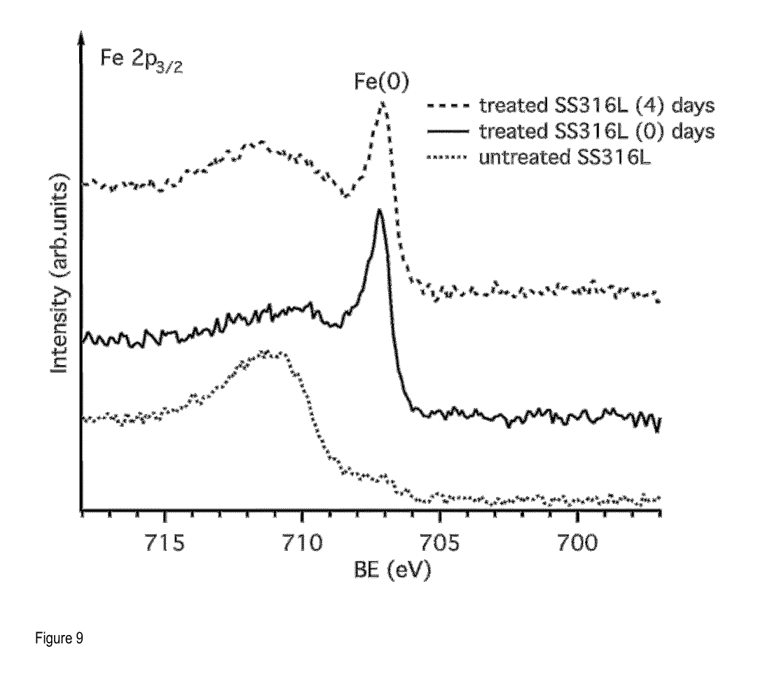

The influence of the duration of the electrochemical polishing treatment was studied. FIGS. 7, 8, and 9 shows the XPS spectra of Ni 2p_{3/2}, Cr 2p_{3/2} and Fe 2p_{3/2} core level for untreated SS 316L (bottom) and treated SS 316L (middle) (both from Example 1) and the XPS spectrum for SS 316L electropolished for 4 days (top). These figures reveal that longer electrochemical polishing of bare SS316L produces a nickel/chromium/iron-rich surface.

### Example 3

The influence of the voltage during applied electrochemical polishing treatment was studied. The voltage was varied between 3.5 and 4 V in experiments similarly to Example 1 above. No meaningful differences were noted on the XPS spectra.

### Example 4

The influence of the nature of the graphene precursor was studied. Experiments were carried bout replacing coronene by methanol, ethanol, and propanol, respectively, which were deposited by CVD on a heated target (900° C.) under vacuum. Reduced graphene oxide coatings were successfully produced.

### Comparative Example 1

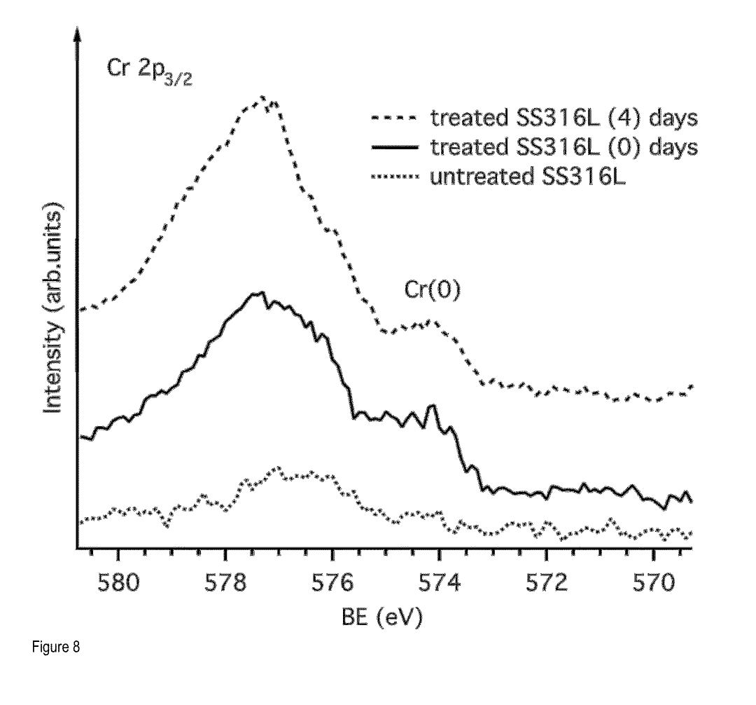

We attempted to grow graphene on untreated SS316L (i.e. stainless steel 316L that has not been electropolished). We were unsuccessful as only amorphous carbon was obtained. FIG. 8 shows (a) Raman spectra corresponding to rGO (top curve, from Example 1) and amorphous carbon (bottom curve) obtained on untreated SS316L on the same area where optical images were taken for: (b) rGO/SS 316L and (c) amorphous carbon/untreated SS316L.

The scope of the claims should not be limited by the preferred embodiments set forth in the examples, but should be given the broadest interpretation consistent with the description as a whole.

### REFERENCES

The present description refers to a number of documents, the content of which is herein incorporated by reference in their entirety. These documents include, but are not limited to, the following:
1. Williams, D. F. Biomaterials. 2008, 29, 2941-53.
2. Balamurugan, A.; Rajeswari, S.; Balossier, G.; Rebelo, A. H. S.; Ferreira, J. M. F. Mater. Corros. 2008, 59, 855-869.
3. Zeng, R.; Dietzel, W.; Witte, F.; Hort, N.; Blawert, C. Adv. Eng. Mater. 2008, 10, B3-B14.
4. Airoldi, F.; Colombo, A.; Tavano, D.; Stankovic, G.; Klugmann, S.; Paolillo, V.; Bonizzoni, E.; Briguori, C.; Carlino, M.; Montorfano, M.; Liistro, F.; Castelli, A.; Ferrari, A.; Sgura, F.; Di Mario, C. Am. J. Cardiol. 2004, 93, 474-7.
5. Raval, A.; Choubey, A.; Engineer, C.; Kothwala, D. J. Biomater. Appl. 2005, 19, 197-213.
6. Bayram, C.; Mizrak, A. K.; Aktürk, S.; Kursaklio\check{g}lu, H.; Iyisoy, A.; Ifran, A.; Denkbas, E. B. Biomed. Mater. 2010, 5, 055007.
7. Broaddus, W. C.; Holloway, K. L.; Winters, C. J.; Bullock, M. R.; Graham, R. S.; Mathern, B. E.; Ward, J. D.; Young, H. F. J. Neurosurg. 2002, 96, 244-7.
8. Reclaru, L.; Lerf, R.; Eschler, P. Y.; Meyer, J. M. Biomaterials. 2001, 22, 269-79.
9. Kraft, C. N.; Burian, B.; Perlick, L.; Wimmer, M. A.; Wallny, T.; Schmitt, O.; Diedrich, O. J. Biomed. Mater. Res. 2001, 57, 404-12.
10. Neumann, P.; Bourauel, C.; Jäger, A. J. Mater. Sci. Mater. Med. 2002, 13, 141-7.
11. Yonekura, Y.; Endo, K.; lijima, M.; Ohno, H.; Mizoguchi, I. Dent. Mater. J. 2004, 23, 197-202.
12. Bertrand, O. F.; Sipehia, R.; Mongrain, R.; Rodes, J.; Tardif, J. C.; Bilodeau, L.; Cote, G.; Bourassa, M. G. J.
13. Ryan, M. P.; Williams, D. E.; Chater, R. J.; Hutton, B. M.; McPhail, D. S. Nature. 2002, 415, 770-4.
14. Lee, C.; Wei, X.; Kysar, J. W.; Hone, J. Science 2008, 321, 385-8.
15. Chen, S.; Brown, L.; Levendorf, M.; Cai, W.; Ju, S.-Y.; Edgeworth, J.; Li, X.; Magnuson, C. W.; Velamakanni, A.; Piner, R. D.; Kang, J.; Park, J.; Ruoff, R. S. ACS. Nano. 2011, 5, 1321-7.
16. Prasai, D.; Tuberquia, J. C.; Harl, R. R.; Jennings, G. K.; Rogers, B. R.; Bolotin, K. I. ACS. Nano. 2012, 6, 1102-8.
17. Zhou, F.; Li, Z.; Shenoy, G. J.; Li, L.; Liu, H. ACS. Nano. 2013, 7, 6939-6947.
18. Schriver, M.; Regan, W.; Gannett, W. J.; Zaniewski, A. M.; Crommie, M. F.; Zettl, A. ACS. Nano. 2013, 7, 5763-8.
19. Bunch, J. S.; Verbridge, S. S.; Alden, J. S.; van der Zande, A. M.; Parpia, J. M.; Craighead, H. G.; McEuen, P. L. Nano. Lett. 2008, 8, 2458-62.
20. Loh, K. P.; Bao, Q.; Eda, G.; Chhowalla, M. Nat. Chem. 2010, 2, 1015-24.
21. Cui, Y.; Kim, S. N.; Naik, R. R.; McAlpine, M. C. Acc. Chem. Res. 2012, 45, 696-704.
22. Sahu, A.; Choi, W. II; Tae, G. Chemical communications (Cambridge, England) 2012, 48, 5820-2.
23. Liu, Z.; Robinson, J. T.; Sun, X.; Dai, H. J. Am. Chem. Soc. 2008, 130, 10876-7.
24. Kim, Y.-K.; Kim, M.-H.; Min, D.-H. Chem. Commun. 2011, 47, 3195-7.
25. Robinson, J. T.; Tabakman, S. M.; Liang, Y.; Wang, H.; Casalongue, H. S.; Vinh, D.; Dai, H. J. Am. Chem. oc. 2011, 133, 6825-31.
26. Gaussian 09, Revision A.1, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zhen, and D. J. F. Gaussian 09.
27. Becke, A. D. J. Chem. Phys. 1993, 98, 5648.
28. Grosvenor, A. P.; Biesinger, M. C.; Smart, R. S. C.; McIntyre, N. S. Surf. Sci. 2006, 600, 1771-1779.
29. Talyzin, A. V.; Luzan, S. M.; Leifer, K.; Akhtar, S.; Fetzer, J.; Cataldo, F.; Tsybin, Y. 0.; Tai, C. W.; Dzwilewski, A.; Moons, E. J. Phys. Chem. C 2011, 115, 13207-13214.
30. Tuinstra, F. J. Chem. Phys. 1970, 53, 1126.
31. Moon, I. K.; Lee, J.; Ruoff, R. S.; Lee, H. Nat. Commun. 2010, 1, 73.
32. Eigler, S.; Dotzer, C.; Hirsch, A. Carbon. NY 2012, 50, 3666-3673.
33. Jung, I.; Rhyee, J.-S.; Son, J. Y.; Ruoff, R. S.; Rhee, K.-Y. Nanotechnology 2012, 23, 025708.
34. Duong, D. L.; Han, G. H.; Lee, S. M.; Gunes, F.; Kim, E. S.; Kim, S. T.; Kim, H.; Ta, Q. H.; So, K. P.; Yoon, S. J.; Chae, S. J.; Jo, Y. W.; Park, M. H.; Chae, S. H.; Lim, S. C.; Choi, J. Y.; Lee, Y. H. Nature. 2012, 490, 235-9.
35. Lerf, A.; He, H.; Forster, M.; Klinowski, J. J. Phys. Chem. B 1998, 102, 4477-4482.
36. Boukhvalov, D. W.; Katsnelson, M. I. J. Am. Chem. Soc. 2008, 130, 10697-701.
37. Sevingli, H.; Topsakal, M.; Durgun, E.; Ciraci, S. Phys. Rev. B 2008, 77, 195434.
38. Valencia, H.; Gil, A.; Frapper, G. J. Phys. Chem. C 2010, 114, 14141-14153.
39. Zhang, B.; Lee, W. H.; Piner, R.; Kholmanov, I.; Wu, Y.; Li, H.; Ji, H.; Ruoff, R. S. ACS. Nano. 2012, 6, 2471-6.
40. John, R.; Ashokreddy, A.; Vijayan, C.; Pradeep, T. Nanotechnology 2011, 22, 165701.
41. Novoselov, K. S.; Geim, A. K.; Morozov, S. V; Jiang, D.; Zhang, Y.; Dubonos, S. V; Grigorieva, I. V; Firsov, A. A. Science 2004, 306, 666-9.
42. Peng, T.; Lv, H.; He, D.; Pan, M.; Mu, S. Sci. Rep. 2013, 3, 1148.
43. Bolen, M.; Harrison, S.; Biedermann, L.; Capano, M. Phys. Rev. B 2009, 80, 115433.
44. Kim, K. S.; Zhao, Y.; Jang, H.; Lee, S. Y.; Kim, J. M.; Kim, K. S.; Ahn, J.-H.; Kim, P.; Choi, J.-Y.; Hong, B. H. Nature. 2009, 457, 706-10.
45. Reina, A.; Jia, X.; Ho, J.; Nezich, D.; Son, H.; Bulovic, V.; Dresselhaus, M. S.; Kong, J. Nano. Lett. 2009, 9, 30-5.
46. Zhu, Y.; Murali, S.; Cai, W.; Li, X.; Suk, J. W.; Potts, J. R.; Ruoff, R. S. Adv. Mater. 2010, 22, 3906-24.
47. John, R.; Ashokreddy, A.; Vijayan, C.; Pradeep, T. Nanotechnology 2011, 22, 165701.
48. Handbook of Stainless Steels, Donald Peckner and I. M. Bernstein, McGraw-Hill Book Company, New York, NY, (1977)
49. Gullapalli. H, Reddy. A. L. M, Kilpatrick. S, Dubey. M, and Ajayan. P. M. Small. 2011, 12, 1697-1700.
50. G. D. Yuana, W. J. Zhanga, Y. Yanga, Y. B. Tanga, Y. Q. Lia, J. X. Wang, X. M. Mengd, Z. B. Hea, C. M. L. Wub, I. Belloa, C. S. Leea, S. T. Leea, Chem. Phys. Lett. 2009, 467, 361-364.
51. Jianjun Wang, Mingyao Zhu, Ron A. Outlaw, Xin Zhao, Dennis M. Manos, Brian C. Holloway. Carbon. 2004, 42, 2867-2872.

1. A method of producing a graphene coating on a stainless steel surface, the method comprising the steps of:
electrochemically polishing of the stainless steel surface, and
heating the polished stainless steel surface in contact with a carbon precursor,
wherein said electrochemical polishing is carried out in an electrochemical cell comprising:
an electrolyte,
a cathode, and
the stainless steel surface as an anode,
the cathode and the anode being submerged in the electrolyte.

2. The method of claim 1, wherein the cathode is made of copper or stainless steel.

3. The method of claim 1, wherein the electrolyte is a mixture of a phosphoric acid and sulfuric acid.

4. The method of claim 1, further comprising cleaning the stainless steel surface prior to electrochemical polishing.

5. The method of claim 1, further comprising cleaning the stainless steel surface after electrochemical polishing.

6. The method of claim 1, further comprising keeping the polished stainless steel surface in the electrolyte up until the heating in contact with the carbon precursor is carried out.

7. The method of claim 1, wherein a solution of the carbon precursor has been cast on the stainless steel surface and allowed to dry before heating.

8. The method of claim 1, wherein, during heating, the carbon precursor is gasified and allowed to reach the stainless steel surface.

9. The method of claim 1, wherein the carbon precursor is an organic compound comprising carbon and hydrogen atoms, optionally oxygen and/or nitrogen atoms and/or halogen atoms, but free of metallic atoms.

10. The method of claim 9, wherein the carbon precursor is an alkane, an alcohol or an acid.

11. The method of claim 9, wherein the carbon precursor comprises one or more fused aromatic rings.

12. The method of claim 11, wherein the carbon precursor is pentacene, anthracene, tetracene, naphthalene, and coronene.

13. The method of claim 12, wherein the carbon precursor is coronene.

14. The method of claim 1, wherein the stainless steel surface is heated at temperature of about 600° C. or more.

15. The method of claim 14, wherein the stainless steel surface is heated at temperature of about 800° C.

16. The method of claim 1, wherein the stainless steel surface is heated for about 30 minutes.

17. The method of claim 1, wherein the stainless steel surface is heated in a vacuum.

18. The method of claim 1, wherein the stainless steel surface is heated in a reducing atmosphere.

19. The method of claim 1, wherein the stainless steel surface is heated in an atmosphere of the carbon precursor.

20. The method of claim 1, further comprising quickly cooling the stainless steel surface.
